(19) United States
(12) Patent Application Publication
(10) Pub. No.: US 2017/0205112 A1
(43) Pub. Date: Jul. 20, 2017

(54) SYSTEMS AND METHODS FOR WATER GENERATION FROM FIN FAN COOLERS

(71) Applicant: Frank J. Cain, Naples, FL (US)

(72) Inventor: Frank J. Cain, Naples, FL (US)

(21) Appl. No.: 15/407,594

(22) Filed: Jan. 17, 2017

Related U.S. Application Data
(60) Provisional application No. 62/280,196, filed on Jan. 19, 2016.

(51) Int. Cl. F24F 13/22; H05K 7/20; F01K 9/00

(52) U.S. Cl. CPC F24F 13/222; F01K 9/003; H05K 7/20209; F24F 2221/56

(57) ABSTRACT

A water generation system and method for an industrial plant is disclosed. The system comprises a water collection system adapted to capture condensed water from the condensation surface from an ambient air conditioning system comprising a pre-cooler or chiller and a condensation surface, wherein the pre-cooler/chiller reduces the temperature of the condensation surface to a temperature at which moisture in the ambient air will condense on the condensation surface.

### REFERENCE TO RELATED APPLICATIONS

The present application claims priority to Provisional U.S. Application No. 62/280,196, filed Jan. 19, 2016, and entitled “SYSTEMS AND METHODS FOR WATER GENERATION FROM FIN FAN COOLERS”, which is incorporated in its entirety.

### BACKGROUND

1. Field of the Invention

This invention is directed to systems and methods of extracting water from pre-cooled air. Specifically, the invention is directed to systems and methods of extracting water from the pre-cooled air in fin fan coolers and air cooled condensers.

2. Description of the Background

Many industrial processes, including but not limited to manufacturing, refining, power generation, waste processing, air conditioning, agricultural process, transportation systems, and computing systems require at least some cooling during the process. For example, waste gases, liquids, and/or vapors from a manufacturing plant may need to be cooled prior to being emitted into the environment. Common methods of cooling employ a fin fan cooler, air cooled condenser, or heat exchanger.

Fin fan coolers and air cooled condensers are typically large installations located at the processing plant that use air flow to reduce the temperature of condensed gases, liquids, and vapors exiting the facilities or operating equipment of the processing plant. Such facilities may include, for example, steam generators, flash evaporators, and gas extraction units. Fin fan coolers and air cooled condensers typically have one or more pipes to convey the hot fluids. The pipes may pass through the fin fan coolers once or multiple times. Usually, ambient air is forced over the pipes. The air can be transmitted by wind (natural draft), fans, suction, or another method. As the air passes over the pipes, the materials contained therein are cooled by transfer of heat to the air on the outside of the pipes and the attached fins. To increase the surface area of the pipes, and therefore increase the cooling effect, surface expanders or fins are coupled to the pipes. For example, the fins can be welded, screwed, bolted or affixed in another manner to the pipes. The cooled fluids can then be further cooled using conventional heat exchangers or are passed on for further processing.

Fin fan coolers are often positioned on elevated structures well above the ground, standing on structural stanchions that permit unrestricted airflow to contact the heated surfaces of the piping carrying the fluids. Generally, these box-like structures carrying the fluids may be twenty or thirty feet above ground. The air movement using induced or forced draft fans may have very large blades to draw air over the hot surface of the pipes and fins. In many installations, there may be six to ten fans operating simultaneously. The fan blades may be variably programmable and the fan speeds may be adjustable to account for temperature variation in the ambient air and the amount of cooling required. The inflow fluids generally are distributed in a head-end distribution box and the outlet fluids collected in tail-end collection boxes for flows to secondary application or reuse. The distribution and collection boxes may arrange flows to and from the piping for maximum contact with the ambient air flowing over them.

Ambient air varies greatly with weather conditions causing the air flows over the fin fan structures to change according to temperatures, humidity, and air quality. Temperature changes are accommodated by changing fan speed and the pitch of the blades. Air quality concerns result in maintenance shut downs for cleaning of piping, fins, and fan blades. Humidity, or the amount of moisture entrapped in the air in the form of water vapor, presents a complicated set of effects on the fin fan coolers. The most difficult result of high humidity on a fin fan cooler is corrosion of the piping and fan systems. The extended surface fins are generally of mild steel as are most piping materials. Even in the case of copper alloys of stainless materials, corrosion is an ever present problem Eliminating moisture prior to air flow over the air coolers is a desirable approach to reducing corrosion.

Many of the chemical plants and refineries in the United States are located in the Gulf Coast, an area noteworthy for high humidity and very warm days. Many power plants are in Florida and the Gulf Coast as well as Southern California. There are many more similar plants around the world in areas of high humidity and temperatures, especially in South Asia and the Middle East. Many of those installations use fin fan coolers as an integral part of their operations.

### SUMMARY

The present invention overcomes the problems and disadvantages associated with current strategies and designs and provides new tools and methods for pre-cooling ambient air and generating water from the air.

One embodiment of the invention is directed to a water generation system for an industrial plant. The water generation system comprises a condensation surface adapted to condense and collect moisture from ambient air, and an ambient air conditioning system comprised of a pre-cooler or chiller, wherein the pre-cooler or chiller reduces the temperature of the condensation surface to a temperature at which moisture in the ambient air will condense on the condensation surface.

In a preferred embodiment, the ambient air conditioning system cools and dehumidifies the ambient air, and collects water resulting from cooled and dehumidified air into a cooling unit of the industrial plant. Preferably, the cooling unit reduces the temperature of one or more process fluids of the industrial plant. The cooling unit is preferably a fin fan cooler or similar air cooled condenser.

Preferably, the pre-cooler or chiller is adapted to provide cooled refrigerant to the condensation surface. The system preferably further comprises at least one chilling coil, wherein the chilling coil transmits the refrigerant from the pre-cooler or chiller to the condensation surface. Preferably, the chilling coil is the condensation surface. Preferably, the chilling coil has an internal temperature at or below 32° F. In a preferred embodiment, the collected condensed water is used in a process of the industrial plant or replaces water purchased by the plant or is exported.

Preferably, the industrial plant is at least one of a manufacturing plant, a refinery, a power generation plant, a waste processing plant, an air conditioning unit, an agricultural processing plant, a transportation system, and a computing system. Preferably, the cooling unit intakes ambient air and cooled air from the ambient air conditioning system. The cooling unit preferably intakes only cooled air from the ambient air conditioning system.

Another embodiment of the invention is directed to a method of generating water for an industrial plant and cooling process fluids in the industrial plant. The method comprises the steps of condensing water out of the ambient air, collecting the condensed water, cooling ambient air, passing the cooled air through a cooling unit, and passing the process fluids though pipes in the cooling unit, wherein the cooled air contacts the pipes in the cooling unit and cools the process fluids.

Preferably, the cooling unit is a fin fan cooler or another air condensers. In a preferred embodiment, the method further comprises providing cooled refrigerant to cool the ambient air from a chiller. Preferably, the method further comprises coupling the chiller to at least one chilling coil, wherein the chilling coil transmits the refrigerant from the chiller and comes into contact with the ambient air. In a preferred embodiment, the chilling coil has an internal temperature at or below 32° F. The method preferably further comprises using the collected condensed water in a process of the industrial plant or replacing water purchased by the plant.

Preferably, the industrial plant is at least one of a manufacturing plant, a refinery, a power generation plant, a waste processing plant, an air conditioning unit, an agricultural processing plant, a transportation system, and a computing system. In a preferred embodiment, the cooling unit intakes ambient air and cooled air. Preferably, the cooling unit intakes only cooled air.

Another embodiment of the invention is directed to a method of retrofitting an industrial plant. The method comprises installing at, no cost by an installer, the water generation as recited herein, and the installer receiving at least a portion of savings achieved by efficiencies of the water generation system.

Other embodiments and advantages of the invention are set forth in part in the description, which follows, and in part, may be obvious from this description, or may be learned from the practice of the invention.

### DESCRIPTION OF THE FIGURES

FIG. 1 depicts an embodiment of a pre-cooler added to a fin fan cooler.

FIG. 2 depicts an embodiment of multiple pre-cooler added to a fin fan cooler.

### DESCRIPTION OF THE INVENTION

As embodied and broadly described herein, the present invention is directed to modifications to fin fan coolers to reduce the humidity and air temperature of the ambient air prior to the ambient air coming into contact with the fins of the cooling pipes. Preferably, the system captures condensed water for in-plant use. The lower temperature and resultant increase in air density preferably increases the efficiency of the fin fan coolers and offsets the increase in pressure drop due to the addition of cooling water or chilled fluid modules.

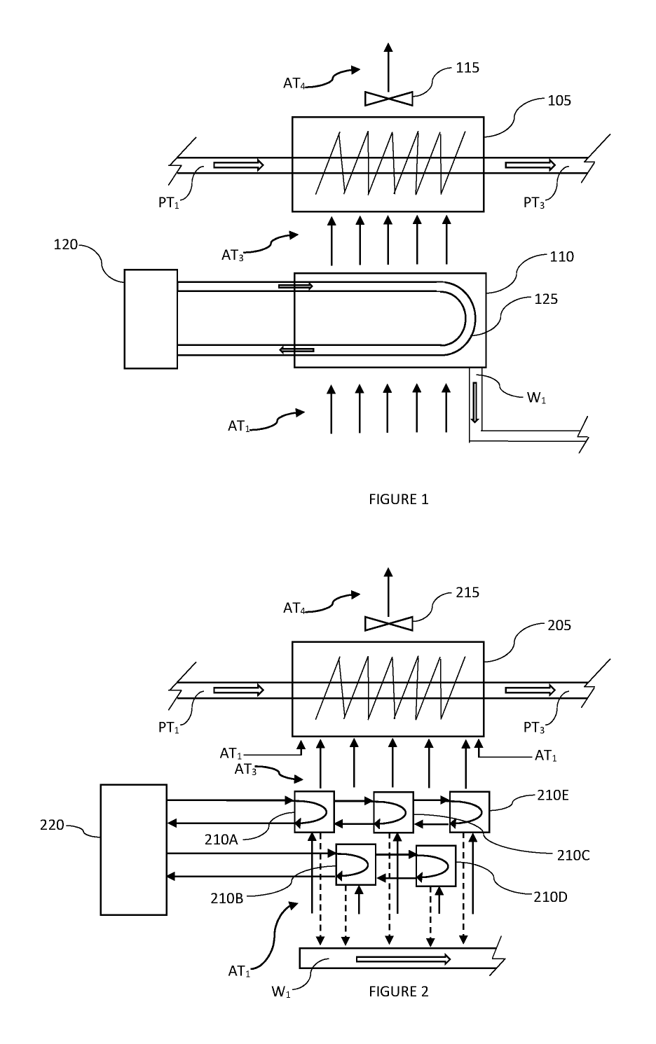

FIG. 1 depicts an embodiment of a modular addition to a fin fan cooler 105. While the invention is described employing fin fan coolers, any type of cooling device can be utilized; for example, other air cooled condensers or heat exchangers. The ambient air conditioning system or pre-cooler 110 is preferably located up-stream of the ambient airflow that enters the fin fan cooler 105. For example, as depicted, the ambient air AT₁ passes through the pre-cooler 110, where it is cooled and dehumidified. The cooled and dehumidified air AT₃ then enters the fin fan cooler 105 and is exhausted as AT₄. The air may be sucked though both the pre-cooler 110 and the fin fan cooler 105 by induced draft fan 115. In other embodiments, the air may be forced through the system by a fan, may use wind, natural draft, or another air movement method.

The pre-cooler 110 may be in place directly adjacent to the fin fan cooler 105 or at a distance from the fin fan cooler 105. If the pre-cooler 110 is placed at a distance to the fin fan cooler 105, ambient air AT₁ may also enter the fin fan cooler 105. As shown in FIG. 1, one pre-cooler 110 is implemented, however another number of pre-cooler 110 can be installed. The pre-cooler 110 can be in series, in parallel, or a combination thereof.

Chiller modules 120 are small packaged units that sub cool an entrapped fluid for use producing low freezing temperatures (usually 30° F.) for special separation technologies and for cold storage. The chilling medium can be water, alcohol, ammonia, ethylene glycol, fluorocarbons, hydrocarbons, or other refrigerants and combinations thereof. Most chemical plants have large chiller plants that are used intermittently. Many refineries also have packaged chiller units in utility service. Power plants generally do not need chilling fluids. Chemical plants and gas separation plants are likely to have cold boxes, a unit that uses reversing heat exchangers to reduce the temperature of special fluids to low Rankine (sub-freezing) temperatures for gas separation and research purposes. Refineries and power plants rarely have cold boxes. Many times, chillers and cold boxes are underutilized and could be put into more continuous service.

Preferably, pre-cooler 110 is comprised of one or more tubes or chiller coils 125. The chiller coils 125 preferably traverse the pre-cooler 110 multiple times to increase the surface area that comes into contact with the air passing there through. Preferably, the chiller coils 125 are coupled to chiller 120. The chilling medium exits chiller 120 at a predetermined temperature into chiller coils 125. The chilling medium cools the chiller coils 125, which in turn cool the air passing over the chiller coils 125. As the air cools, the chiller coils 125 and the chilling medium get warmer. The warmed chilling medium is then returned to the chiller 120 where it is re-cooled in a closed-loop system.

The chiller coils 125 are preferably a metal, such as brass, copper, iron, or steel. However, other naturally occurring or manmade materials can be used. The internal temperature of the chiller coils 125 at the point where they come into contact with the ambient air is preferably at or below freezing temperatures (preferably about 30° F.). Preferably, the ambient air is cooled below the dew point. At this temperature, the condensation of moisture in air is highly efficient as it can capture the latent heat of moisture (between 37° and 39° F.). Preferably, chiller coils 125 provide a condensation surface. However, other surfaces can be coupled to chiller coils 125 to provide a surface for condensation.

Preferably, within the pre-cooler 110, ambient air can flow freely over the chiller coils 125 drawn through by the fin fan cooler fans 115. The air is cooled by the lower temperatures on the coils 125 condensing the moisture in the air and collecting the water at the bottom of the pre-cooler 110. The condensed water can be collected in troughs, fabric, drainage channels, or other water collecting devices. The pre-cooler 110 preferably has tubing headers on the inflow and outflow ends to supply the chilled fluid and to collect the outflow for return to the plant's existing chillers or cold boxes. Output water Wi is preferably piped into a storage tank for direct use in the plant or adding to the plant's utility water systems or exported to another user.

FIG. 2 depicts another embodiment of the fin fan cooler 205 with multiple pre-coolers 210A-E. As can be seen in FIG. 2, the pre-coolers 210A-E are preferably off set from each other, allowing ambient air to pass both through the pre-coolers 210A-E and around the pre-coolers 210A-E. Additionally, the pre-coolers 210D and 210E may be positioned at different depths. Ambient air AT₁ enters the various pre-coolers 210A-E and cooled and dehumidified air AT₃ exits the various pre-coolers 210A-E. Preferably, both ambient air AT₁ and the cooled and dehumidified air AT₃ enters the fin fan cooler 205. Furthermore, the condensed water W₁ is collected from the various pre-coolers 210A-E. Condensed water W₁ may be treated prior to being used by the plant or exported.

Industrial plants regularly purchase make-up water from municipal water districts. Most of this water is used to for Boiler Feed Water Systems (BFW) and for make-up water to Cooling Towers (CT). These BFW and CT systems are regularly “blown down” to remove concentrations of heavy metals and chemicals. The BFW and CTs also have extensive pretreatment systems for make-up water to condition the water to prevent internal corrosion, foaming and coating of the equipment and its piping. The amount blown down is as high as 20% of the flow in CT systems and 4% for BFW systems. These large losses can result in a very high cost of purchased water. By using the condensed water described herein, a large portion of the required make-up water purchased from the municipality can be replaced and much of the pre-treatment can be avoided.

The amount of water in atmospheric air is measured by dew point and by humidity. Dew point is the temperature at which water will begin to condense out of the air at a specific water vapor concentration in the air. Relative humidity is the ratio of actual water in the air to the maximum water the air can contain at a specific temperature and is expressed as a percentage. The higher the percentage of relative humidity the more water vapor is in the air at a given temperature. 100% relative humidity is saturated air and water will condense on any surface with a lower temperature than the air temperature. There is a band of temperatures and relative humidity's that will produce an ideal condition for the condensation of water. Generally, higher temperatures and high relative humidity produce the greatest amount of product water. The very low temperatures on the cooling coil containing chilled fluid will preferably lower the temperature of the air and increase the amounts of water that can be condensed. The pre-coolers are preferably programmed to operate only when there are temperatures and relative humidity that are within a favorable band.

The amount of make-up water produced at any one facility containing modified fin fan coolers is a function of the climate of that physical location. In some hot/humid areas there may be several thousand gallons produced per day. Potentially, a four (4) section fin fan cooler, of 20 ft by 8 ft, each, operating with pre-coolers at an average temperature of 80° F. and 70% humidity where the pre-coolers reduce the inlet air temperature by about 12° F. will produce about 1350 gallons of condensed atmospheric raw water within about 24 hours. The calculations were approximated based on an existing fin fan cooler at a U.S. power plant was simulated to be modified with the addition of chilling coils. The stipulated conditions were an atmospheric air temperature of 90° F. and 80% humidity. In theory, the chiller provided inlet air conditions of 38° F. across 100 MW air flow of 20 million cubic feet across the air cooler. The resultant water recovery was approximately 3650 gallons per minute.

Additionally, as the air entering the fin fan cooler is at a lower temperature than the ambient air, the fin fan cooler may be able to reduce the temperature of the process fluid (PT₁ in FIG. 1) more efficiently than without the pre-cooler. Such efficiencies may reduce the need for purchased electricity or other energy sources.

In some embodiments, one or more water generating system may be installed onto an existing factory's fin fan coolers. The water generating system may be coupled to existing chillers or have new chillers installed as well. In order to reduce the cost of the installation, the installer may charge a minimal amount or nothing upfront to install the water generating system. Instead, the installer may receive a portion of the cost savings achieved by collecting water from the pre-coolers. For example, if installer does not charge to install the water generating system and the factory sees a decrees in the cost of operating the fin fan coolers and purchasing and treating make-up water, the installer may receive a percentage of the savings as payment.

Other embodiments and uses of the invention will be apparent to those skilled in the art from consideration of the specification and practice of the invention disclosed herein. All references cited herein, including all publications, U.S. and foreign patents and patent applications, are specifically and entirely incorporated by reference. The term comprising, where ever used, is intended to include the terms consisting and consisting essentially of. Furthermore, the terms comprising, including, and containing are not intended to be limiting. It is intended that the specification and examples be considered exemplary only with the true scope and spirit of the invention indicated by the following claims.

1. A water generation system for an industrial plant, comprising:
a condensation surface adapted to condense and collect moisture from ambient air;
an ambient air conditioning system comprised of a pre-cooler or chiller, wherein the pre-cooler or chiller reduces the temperature of the condensation surface to a temperature at which moisture in the ambient air will condense on the condensation surface.

2. The water generation system of claim 1, wherein the ambient air conditioning system cools and dehumidifies the ambient air, and collects water resulting from cooled and dehumidified air into a cooling unit of the industrial plant.

3. The water generation system of claim 2, wherein the cooling unit reduces the temperature of one or more process fluids of the industrial plant.

4. The water generation system of claim 2, wherein the cooling unit is a fin fan cooler or similar air cooled condenser.

5. The water generation system of claim 1, wherein the pre-cooler or chiller is adapted to provide cooled refrigerant to the condensation surface.

6. The water generation system of claim 5, further comprising at least one chilling coil, wherein the chilling coil transmits the refrigerant from the pre-cooler or chiller to the condensation surface.

7. The water generation system of claim 6, wherein the chilling coil is the condensation surface.

8. The water generation system of claim 6, wherein the chilling coil has an internal temperature at or below 32° F.

9. The water generation system of claim 1, wherein the collected condensed water is used in a process of the industrial plant or replaces water purchased by the plant or is exported.

10. The water generation system of claim 1, wherein the industrial plant is at least one of a manufacturing plant, a refinery, a power generation plant, a waste processing plant, an air conditioning unit, an agricultural processing plant, a transportation system, and a computing system.

11. The water generation system of claim 2, wherein the cooling unit intakes ambient air and cooled air from the ambient air conditioning system.

12. The water generation system of claim 1, wherein the cooling unit intakes only cooled air from the ambient air conditioning system.

13. A method of generating water for an industrial plant and cooling process fluids in the industrial plant, comprising:
condensing water out of the ambient air;
collecting the condensed water;
cooling ambient air;
passing the cooled air through a cooling unit; and
passing the process fluids though pipes in the cooling unit, wherein the cooled air contacts the pipes in the cooling unit and cools the process fluids.

14. The method of claim 13, wherein the cooling unit is a fin fan cooler or another air condensers.

15. The method of claim 13, further comprising providing cooled refrigerant to cool the ambient air from a chiller.

16. The method of claim 15, further comprising coupling the chiller to at least one chilling coil, wherein the chilling coil transmits the refrigerant from the chiller and comes into contact with the ambient air.

17. The method of claim 16, wherein the chilling coil has an internal temperature at or below 32° F.

18. The method of claim 13, further comprising using the collected condensed water in a process of the industrial plant or replacing water purchased by the plant.

19. The method of claim 13, wherein the industrial plant is at least one of a manufacturing plant, a refinery, a power generation plant, a waste processing plant, an air conditioning unit, an agricultural processing plant, a transportation system, and a computing system.

20. The method of claim 13, wherein the cooling unit intakes ambient air and cooled air.

21. The method of claim 13, wherein the cooling unit intakes only cooled air.

22. A method of retrofitting an industrial plant, comprising:
installing at, no cost by an installer, the water generation system of claim 1; and
the installer receiving at least a portion of savings achieved by efficiencies of the water generation system of claim 1.
